(19) United States
(12) Patent Application Publication
(10) Pub. No.: US 2024/0387597 A1
(43) Pub. Date: Nov. 21, 2024

(54) IMAGE SENSOR

(71) Applicant: Samsung Electronics Co., Ltd., Suwon-si (KR)

(72) Inventors: Gwideok Ryan LEE, Suwon-si (KR); Jeongsoon KANG, Suwon-si (KR); Gyunha PARK, Suwon-si (KR); Jongeun PARK, Suwon-si (KR); Dongseok CHO, Suwon-si (KR)

(73) Assignee: Samsung Electronics Co., Ltd., Suwon-si (KR)

(21) Appl. No.: 18/390,713

(22) Filed: Dec. 20, 2023

(30) Foreign Application Priority Data
May 17, 2023 (KR) 10-2023-0064019

(51) Int. Cl. H01L 27/146; H04N 25/63

(52) U.S. Cl. CPC H01L 27/14643; H01L 27/14612; H01L 27/1463; H01L 27/14636; H04N 25/63

(57) ABSTRACT

An image sensor includes a first structure and a second structure, each having at least one pixel and sequentially stacked in a vertical direction. Each of the pixels may include a photodiode portion, provided in the first structure, and a pixel circuit portion connected to the photodiode portion provided in the first structure.

### CROSS-REFERENCE TO RELATED APPLICATION(S)

This application claims benefit of priority to Korean Patent Application No. 10-2023-0064019, filed on May 17, 2023, in the Korean Intellectual Property Office, the disclosure of which is incorporated herein by reference in its entirety.

### BACKGROUND

The present disclosure relates to image sensors.

An image sensing device may include semiconductor elements converting optical information into an electric signal. Such an image sensing device may include a charge coupled device (CCD) image sensing device and a complementary metal-oxide semiconductor (CMOS) image sensing device.

The CMOS image sensor may be abbreviated as a CIS. The CIS may include a plurality of pixels arranged two-dimensionally. Each of the pixels includes a photodiode (PD) and pixel circuits connected to the photodiode. The photodiode serves to convert incident light into an electrical signal, so that a complex structure caused by the pixel circuits makes it difficult to secure full well capacitance (FWC) of a photodiode and defects such as dark current, or the like, occurs.

### SUMMARY

Example embodiments provide image sensors having increased full well capacitance.

Example embodiments provide image sensors having reduced defects, such as related to dark current.

According to some aspects of the inventive concepts, there is provided an image sensor including a first structure and a second structure, each having at least one pixel and sequentially stacked in a vertical direction, each of the pixels including a photodiode portion in the first structure; and a pixel circuit portion connected to the photodiode portion in the first structure, the photodiode portion including a photoelectric conversion region in the first substrate; a floating diffusion region spaced apart from the photoelectric conversion region; a gate including a transfer channel between the photoelectric conversion region and the floating diffusion region; and a device isolation layer surrounding the photoelectric conversion region, and the device isolation layer including a first isolation layer, surrounding the photoelectric conversion region, and a second isolation layer, having a smaller depth than the first isolation layer and adjacent to only a side of the floating diffusion region, when viewed in plan view.

According to some aspects of the inventive concepts, there is provided an image sensor including a photoelectric conversion region in a first substrate having a first surface and a second surface; a floating diffusion region in the first substrate to be spaced apart from the photoelectric conversion region; a gate of a transfer transistor on a side of the first surface of the first substrate as a transfer channel between the photoelectric conversion region and the floating diffusion region; and a device isolation layer surrounding the photoelectric conversion region, the device isolation layer including a first isolation layer, surrounding the photoelectric conversion region, and a second isolation layer, having a smaller depth than the first isolation layer and adjacent to only a side of the floating diffusion region, when viewed in plan view.

According to some aspects of the inventive concepts, there is provided an image sensor including a pixel including a plurality of transistors, a first structure, a second structure, and a third structure sequentially stacked in vertical direction, the first structure including a transfer transistor among the plurality of transistors, the second structure including remaining transistors other than the transfer transistor, and the third structure a logic circuit, the first structure including a device isolation layer surrounding an active region in the first substrate having the first surface and the second surface; a photoelectric conversion region in the active region; a floating diffusion region in the active region and spaced apart from the photoelectric conversion region; and a gate of the transfer transistor in the active region on a side of the first surface of the first substate as a transfer channel between the photoelectric conversion region and the floating diffusion region, and the device isolation layer including a first isolation layer, surrounding the photoelectric conversion region, and a second isolation layer, having a smaller depth than the first isolation layer, when viewed in plan view, the first isolation layer and the second isolation layer stacked in a vertical direction in a first region adjacent to the floating diffusion region, and the second isolation layer is in the vertical direction in a region other than the first region

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram of an image sensor according to example embodiments.

FIG. 2 is a circuit diagram of a pixel in an image sensor according to some example embodiments.

FIGS. 3A and 3B are conceptual diagrams of a layout of an image sensor according to some example embodiments.

FIG. 4 is a plan view of an image sensor according to some example embodiments.

FIG. 5A is a plan view illustrating a single pixel in FIG. 4, and FIG. 5B is a cross-sectional view taken along line A-A′ of FIG. 5A.

FIG. 6 illustrates an image sensor according to some example embodiments, and a cross-sectional view of an image sensor having a planar transfer gate structure.

FIG. 7 is a cross-sectional view illustrating successively arranged pixels, in an image sensor according to some example embodiments.

FIGS. 8A and 8B are a circuit diagram and a plan view illustrating that four adjacent pixels share a floating diffusion region, in an image sensor according to some example embodiments.

FIG. 9 is a cross-sectional view illustrating a first structure and a second structure are stacked, in an image sensor according to some example embodiments.

FIG. 10 is a cross-sectional view illustrating that a first structure to a third structure are sequentially stacked, in an image sensor according to some example embodiments.

FIG. 11 is a cross-sectional view illustrating that a first structure to a third structure are sequentially stacked, in an image sensor according to some example embodiments.

### DETAILED DESCRIPTION

The present disclosure may be modified in various ways, and may have various example embodiments, among which some example embodiments will be described in detail with reference to the accompanying drawings. However, it should be understood that the description of the some example embodiments of the present disclosure is not intended to limit the present disclosure to a particular mode of practice, and that the present disclosure is to cover all modifications, equivalents, and substitutes included in the spirit and technical scope of the present disclosure.

Hereinafter, example embodiments will be described in detail with reference to the attached drawings. Like reference numerals in the drawings denote like elements, and redundant descriptions thereof will be omitted.

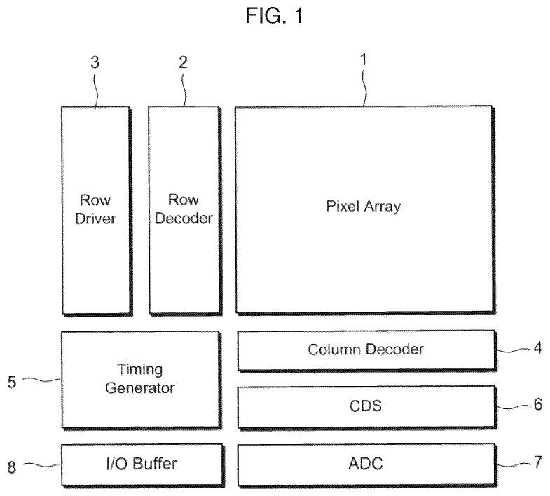

FIG. 1 is a block diagram of an image sensor according to example embodiments.

Referring to FIG. 1, an image sensor according to some example embodiments may include a pixel array 1, a row decoder 2, a row driver 3, a column decoder 4, a timing generator 5, a correlated double sampler (CDS) 6, an analog-to-digital converter (ADC) 7, and an input/output buffer (I/O buffer) 8.

The pixel array 1 may include a plurality of unit pixels arranged two-dimensionally, and may convert an optical signal into an electrical signal. The pixel array 1 may be driven by a plurality of driving signals such as a pixel select signal, a reset signal, and a charge transfer signal from the row driver 3. The converted electrical signal may be provided to the correlated double sampler 6.

The row driver 3 may provide a plurality of driving signals for driving a plurality of unit pixels to the pixel array 1 based on a result decoded by the row decoder 2. When unit pixels are arranged in a matrix, driving signals may be provided for each row.

The timing generator 5 may provide a timing signal and a control signal to row decoder 2 and column decoder 4.

The correlated double sampler 6 may receive the electrical signal generated by the pixel array 1, and may hold and sample the received electrical signal. The correlated double sampler 6 may double-sample a noise level (for example, a specific, desired, or determined noise level) and a signal level of the electrical signal to output a difference level corresponding to a difference between the noise level and the signal level.

The analog-to-digital converter 7 may convert an analog signal, corresponding to the difference level output from the correlated double sampler 6, into a digital signal and then output the digital signal.

The input/output buffer 8 may latch digital signals, and the latched digital signals may be sequentially output to an image signal processing unit, not illustrated, based on results decoded by the column decoder 4.

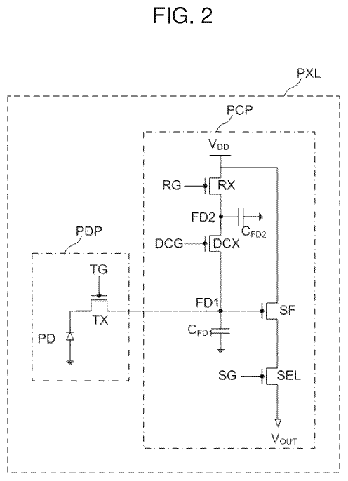

FIG. 2 is a circuit diagram of a pixel in an image sensor according to some example embodiments.

Referring to FIG. 2, a pixel PXL may include a photodiode portion PDP and a pixel circuit portion PCP connected to the photodiode portion PDP.

According to some example embodiments, the image sensor is provided in a stack structure including a multilayer structure, and the photodiode portion PDP and the pixel circuit portion PCP are formed in different structures. Therefore, a circuit diagram of the pixel PXL will be described first, and a detailed structure will be described later.

The photodiode portion PDP may include a photoelectric conversion element PD, a transfer transistor TX, and a floating diffusion region FD, and the pixel circuit portion PCP may include a plurality of pixel transistors.

The pixel transistors of the pixel circuit unit PCP may include a reset transistor RX, a source follower transistor SF, a select transistor SEL, and a dual conversion gain transistor DCX.

In some example embodiments, the single pixel PXL has been described as including four pixel transistors, but example embodiments are not limited thereto and the number of pixel transistors PXL may vary in each pixel.

The photoelectric conversion device PD may generate and accumulate charges corresponding to incident light. The photoelectric conversion device PD may be, for example, a photodiode, a phototransistor, a photogate, a pinned photodiode (PPD), or combinations thereof.

The transfer transistor TX may transfer the charges, accumulated in the photoelectric conversion element PD, to a first floating diffusion region FD1. The transfer transistor TX may be controlled by the transfer signal TG. The transfer transistor TX may be connected to the first floating diffusion region FD1.

The first floating diffusion region FD1 may receive and cumulatively store the charges generated by the photoelectric conversion element PD. The source follower transistor SF may be controlled depending on the amount of photocharges accumulated in the first floating diffusion region FD1.

The reset transistor RX may periodically reset the charges accumulated in the first and second floating diffusion regions FD1 and FD2 according to a reset signal applied to the reset gate electrode RG. For example, a drain terminal of the reset transistor RX may be connected to the dual conversion gain transistor DCX, and a source terminal of the reset transistor RX may be connected to a pixel power supply voltage V_{DD}. When the reset transistor RX and the dual conversion gain transistor DCX are turned on, the pixel power supply voltage V_{DD} may be transmitted to the first and second floating diffusion regions FD1 and FD2. Accordingly, the charges accumulated in the first and second floating diffusion regions FD1 and FD2 may be discharged to reset the first and second floating diffusion regions FD1 and FD2.

The dual conversion gain transistor DCX may be connected between the first floating diffusion region FD1 and the second floating diffusion region FD2. The dual conversion gain transistor DCX may be connected in series to the reset transistor RX through the second floating diffusion region FD2. For example, the dual conversion gain transistor DCX may be connected between the first floating diffusion region FD1 and the reset transistor RX. The dual conversion gain transistor DCX may vary capacitance CFD1 of the first floating diffusion region FD1 in response to the dual conversion gain control signal to vary a conversion gain of the pixel PXL.

For example, when an image is captured, low-illuminance light and high-illuminance light may be simultaneously incident to a pixel array, or high-intensity light and low-intensity light may be simultaneously incident to a pixel array. Accordingly, each pixel may have a conversion gain, variable depending on incident light. For example, when the dual conversion gain transistor DCX is turned off, a unit pixel may have a first conversion gain. On the other hand, when the dual conversion gain transistor DCX is turned on, the unit pixel may have a second conversion gain, greater than the first conversion gain. For example, different conversion gains may be provided in a first conversion gain mode (or a high-illuminance mode) and a second conversion gain mode (or a low-illuminance mode) according to the operation of the dual conversion gain transistor DCX.

When the dual conversion gain transistor DCX is turned off, capacitance of the first floating diffusion region FD1 may correspond to the first capacitance CFD1. When the dual conversion gain transistor DCX is turned on, the first floating diffusion region FD1 may be connected to the second floating diffusion region FD2, and thus capacitance in the first and second floating diffusion regions FD1 and FD2 may be equal to a sum of the first and second capacitances CFD1 and CFD2. For example, when the dual conversion gain transistor DCX is turned on, the capacitance of the first or second floating diffusion region FD1 or FD2 may be increased to reduce a conversion gain. On the other hand, when the dual conversion gain transistor DCX is turned off, the capacitance of the first floating diffusion region FD1 may be decreased to increase a conversion gain.

The source follower transistor SF may be a source follower buffer amplifier generating source-drain current in proportion to the amount of charges of the first floating diffusion region FD1 input to a source follower gate electrode. The source follower transistor SF may amplify a potential change in the floating diffusion region FD, and may output an amplified signal to an output line V_{OUT} through the select transistor SEL. A source terminal of the source follower transistor SF may be connected to a power supply voltage V_{DD}, and a drain terminal of the source follower transistor SF may be connected to a source terminal of the select transistor SEL.

The select transistor SEL may select unit pixels P to be read in units of rows. When the select transistor SEL is turned on by a select signal SG applied a select gate electrode, an electrical signal output to a drain electrode of the source follower transistor SF may be output to the output line V_{OUT}.

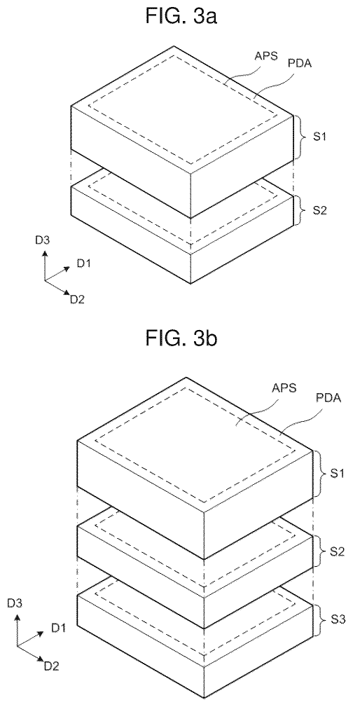

FIGS. 3A and 3B are conceptual diagrams illustrating a layout of an image sensor according to some example embodiments.

Referring to FIGS. 3A and 3B, the image sensor may include a plurality of structures sequentially stacked in one direction. For example, the image sensor may include a first structure S1 and a second structure S2 stacked as illustrated in FIG. 3A, or first to third structures S1, S2, and S3 stacked as illustrated in FIG. 3B.

In FIG. 3A, the first structure S1 may be an upper structure and the second structure S2 may be a lower structure. In FIG. 3B, the first structure S1 may be an upper structure, the second structure S2 may be an intermediate structure, and the third structure S3 may be a lower structure.

A plurality of structures may be provided in the form of a chip, and may have the same size or different sizes. For example, an area of the first structure S1 may be smaller than an area of the second structure S2 and/or the third structure S3 when viewed in plan view.

A bonding portion, not illustrated, may be provided between two adjacent chips to bond the two adjacent chips to each other. Hereinafter, a direction in which the first structure S1 and the second structure S2 are stacked will be defined as a third direction D3, and two directions intersecting each other on a plane perpendicular to the third direction D3 will be defined as a first direction D1 and a second direction D2. However, the first to third directions D1, D2, and D3 are relative directions defined for ease of description, and may be defined to be different from those of an actual object.

The first structure S1 may be a sensor structure in which a photodiode portion PDP (see FIG. 2) is formed. A plurality of pixels may be arranged in a two-dimensional array structure on the first structure S1, and the first structure S1 may have a pixel array region APS.

A pixel circuit portion PCP (see FIG. 2), other than the photodiode portion PDP, and/or a logic circuit, controlling the photodiode portion PDP and the pixel circuit portion PCP, may be mounted on the second structure S2 and/or the third structure S3. For example, in some example embodiments, the pixel circuit part PCP may be provided on the second structure S2 and the logic circuit may be provided on the third structure S3. In some example embodiments, a portion of the pixel circuit portion PCP may be provided on second structure S2, and another portion of the pixel circuit portion PCP and the logic circuit may be provided on the third structure S3. According to some example embodiments, both the pixel circuit portion PCP and the logic circuit may be provided on the second structure S2.

The logic circuits may include circuits processing pixel signals from the pixels. For example, the logic circuits may include a control register block, a timing generator, a row driver, a readout circuit, a ramp signal generator, or the like.

A memory device may be further disposed in the second structure S2 and/or the third structure S3. As the memory device, a dynamic random access memory (DRAM) device, a static random access memory (SRAM) device, a spin-transfer torque magnetic random access memory (STT-MRAM) device, or a flash memory device may be formed in an embedded form. The image sensor may temporarily store a frame image using such a memory device and perform signal processing to significantly reduce a zello effect, resulting in improved operation characteristics of the image sensor. In addition, the memory device of the image sensor may be formed together with the logic devices in an embedded form to simplify a fabrication process and to reduce a size of a product.

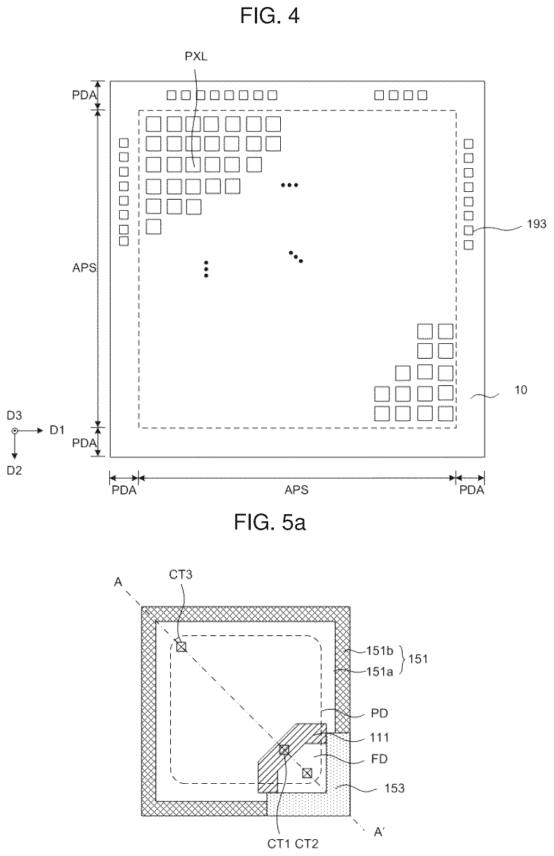

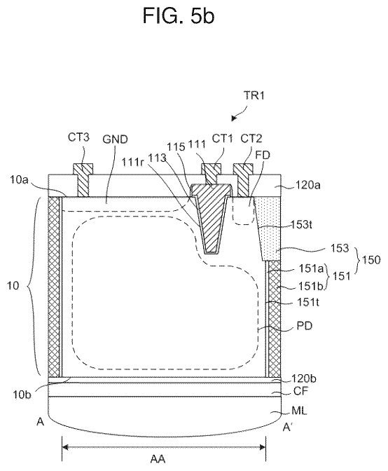

FIG. 4 is a plan view illustrating an image sensor according to some example embodiments, FIG. 5A is a plan view illustrating a single pixel in FIG. 4, and FIG. 5B is a cross-sectional view taken along line A-A′ of FIG. 5A.

Referring to FIGS. 4, 5A, and 5B, a first structure S1 may include a first substrate 10, and a first conductive pattern, a device isolation layer 150, a color filter CF, and a micro lens ML provided on the first substrate 10.

The first substrate 10 may include a pixel array region APS, which is a region in which pixels PXL are provided, and a pad area PDA when viewed in plan view. The pixel array area APS may be disposed in a center of the first substrate 10 when viewed from a plan view. The pixel array region APS may include a plurality of pixels PXL. Each of the pixels PXL may include a photodiode portion PDP (see FIG. 2), provided on a first structure S1, and a pixel circuit portion PCP (see FIG. 2) connected to a photodiode portion PDP provide on a second structure S2 and/or a third structure S3. In some example embodiments, for ease of description, each of the pixels PXL will be described with respect to the photodiode part PDP provided on the first structure S1.

The pixels PXL may output a photoelectric signal from incident light. The pixels PXL may be two-dimensionally arranged to constitute rows and columns. The rows may be parallel to a first direction D1. The columns may be parallel to a second direction D2. In example embodiments, the first direction D1 may be parallel to a first surface 110a of the first semiconductor substrate 110.

The pad region PDA may be an edge region of the first substrate 10. For example, the pad region PDA of the first substrate 10 may be provided between the pixel array region APS and a side surface of the first substrate 10 when viewed in plan view. However, the disposition of the pad region PDA is not limited thereto, and the pad region PDA may be provided on another substrate (for example, a substrate of the second structure S2 or the third structure S3), other than the first substrate 10.

The pad region PDA may surround the pixel array region APS when viewed in plan view. Signal pads 193 may be provided on the pad region PDA. The signal pads 193 may output electrical signals, generated from the pixels PXL, to an external entity. Alternatively, or additionally, an external electrical signal or voltage may be transmitted to the pixels PXL through the signal pads 193. Since the pad region PDA is an edge region of the first substrate 10, the signal pads 193 may be connected (for example, easily or simply connected) to an external entity.

Hereinafter, the pixel array region APS of the first structure S1 of the image sensor will be described in detail.

The first substrate 10 may have a first surface 10a and a second surface 10b opposing each other. The first surface 10a of the first substrate 10 may be a rear surface, and the second surface 10b thereof may be a front surface. Light may be incident to the first surface 10a of the first substrate 10. The first substrate 10 may be a semiconductor substrate or a silicon-on-insulator (SOI) substrate. The first substrate 10 may be, for example, a silicon substrate, a germanium substrate, or a silicon-germanium substrate. The first semiconductor substrate 10 may further include group III elements. The group III elements may be impurities of first conductivity type. Accordingly, the first semiconductor substrate 10 may have the first conductivity type. For example, the first conductivity type impurities may include P-type impurities such as aluminum (Al), boron (B), indium (In), and/or gallium (Ga). In some example embodiments, the first conductivity type will be described as being P-type, but this is only an example and the first conductivity type may be N-type.

A photodiode portion may be provided on the first substrate 10 for each pixel PXL. The photodiode portion may include a photoelectric conversion region PD, and an active region AA including a floating diffusion region FD and a ground region GND.

Photoelectric conversion regions PD may be interposed between the first surface 10a and the second surface 10b of the first substrate 10. The photoelectric conversion regions PD may be doped regions including impurities of the second conductivity type. In some example embodiments, the photoelectric conversion regions PD may include group V elements, and the group V elements may be impurities of the second conductivity type. The impurity of the second conductivity type may have a conductivity type opposite to a conductivity type of the impurity of the first conductivity type. Impurities of the second conductivity type may include N-type impurities such as phosphorus, arsenic, bismuth, and/or antimony. The photoelectric conversion regions PD may be disposed in locations spaced apart from the second surface 10b of the first substrate 10.

The active region AA includes a floating diffusion region FD and a ground region GND.

The ground region GND may be formed in the first substrate 10 of the active region AA. The ground region GND may have the first conductivity type. In some example embodiments, the ground region GND may have the first conductivity type at an impurity concentration higher than an impurity concentration of the first substrate 10. For example, the ground region GND may be an impurity region 103 formed by implanting heavily doped P-type impurities (P⁺⁺ impurities) into the P-type first substrate 10.

A ground voltage may be applied to the ground region GND. A third contact CT3 may be formed and connected to the ground region GND. The third contact CT3 may provide the ground voltage to the ground region GND.

The floating diffusion region FD may be formed in the first substrate 10 of the active region AA. The floating diffusion region FD may be spaced apart from the photoelectric conversion region PD. Also, the floating diffusion region FD may be spaced apart from the ground region GND. The floating diffusion region FD may have the second conductivity type. Therefore, the floating diffusion region FD may be, for example, a first impurity region 102 formed by implanting N-type impurities into the P-type first substrate 10.

In some example embodiments, the floating diffusion region FD may have the second conductivity type at an impurity concentration, higher than an impurity concentration of the photoelectric conversion region PD. For example, the floating diffusion region FD may be formed by implanting heavily doped N-type impurities (N⁺ impurities) into the P-type first substrate 10. A channel region may be formed between the photoelectric conversion region PD and the floating diffusion region FD.

A first conductive pattern 100 may be provided on the first surface 10a of the first substrate 10. The first conductive pattern 100 may include a transfer transistor, serving as a first transistor TR1, and a first interconnection portion including first to third contacts CT1, CT2, and CT3 connected to the transfer transistor.

In some example embodiments, among transistors constituting a single pixel PXL, a first transistor TR1 provided on the first substrate 10 may be a transfer transistor, and the remaining transistors may not be provided on the first substrate 10. For example, the remaining transistors, other than the transfer transistor, such as a reset transistor, a source follower transistor, a select transistor, or a dual conversion gain transistor may be provided on a substrate of a different structure (a second substrate 20 and/or a third substrate 30 to be described later).

The first transistor TR1, for example, the transfer transistor may include a gate 111 forming a transfer channel between the photoelectric conversion region PD and the floating diffusion region FD, a gate insulating layer 113 insulating the first substrate 10 and the gate 111 from each other, and a gate spacer 115 provided on a side surface of the gate 111.

The gate 111 may be disposed on the second surface 10b of the first substrate 10. The gate 111 may function as an electrode at a gate 111 of the transfer transistor.

The gate 111 may have a buried gate structure. For example, the gate 111 may include a first portion and a second portion. A first portion of the gate 111 may be disposed on the second surface 10b of the first substrate 10. A second portion of the gate 111 may protrude inwardly of the first substrate 10. The second portion of the gate 111 may be provided on an upper surface of the first portion to be connected to the first portion.

The gate 111 may include a metal material, a metal silicide material, polysilicon, or combinations thereof. In this case, the polysilicon may include doped polysilicon.

A gate insulating layer 113 may be interposed between the gate 111 and the first substrate 10. The gate insulating layer 113 may include, for example, a silicon-based insulating material (for example, a silicon oxide, a silicon nitride, and/or a silicon oxynitride) and/or a high-κ material (for example, a hafnium oxide and/or an aluminum oxide).

The gate insulating layer 113 may be interposed between the transfer gate 111 and the first substrate 10. For example, the gate insulating layer 113 may conformally extend along a profile of a side surface and a lower surface of a substrate recess 111r. The transfer gate 111 may be formed on the gate insulating layer 113 to fill at least a portion of the substrate recess 111r. In some example embodiments, the gate insulating layer 113 may further extend along the first surface 10a of the first substrate 10.

The gate insulating layer 113 may include, for example, at least one of a silicon oxide, a silicon nitride, a silicon oxynitride, or a low-κ dielectric material having a lower dielectric constant than the silicon oxide, but example embodiments are not limited thereto. The low-κ dielectric material may include at least one of flowable oxide (FOX), tonen silazane (TOSZ), undoped silicate glass (USG), borosilicate glass (BSG), phosphosilicate glass (PSG), borophosphosilica glass (BPSG), plasma enhanced tetraethylorthosilicate (PETEOS), fluoride silicate glass (FSG), carbon doped silicon oxide (CDO), xerogel, aerogel, amorphous fluorinated carbon, organosilicate glass (OSG), parylene, bis-benzocyclobutenes (BCB), SiLK, polyimide (PI), a porous polymeric material, or combinations thereof. As an example, the gate insulating layer 113 may include a silicon oxide layer.

The gate spacer 115 may be formed on a side surface of the gate 111. The ground region GND may be spaced apart from the gate 111 by the gate spacer 115. In some example embodiments, the ground region GND may be spaced apart from an upper gate 111 by the gate insulating layer 113 and the gate spacer 115. In addition, the gate spacer 115 may be interposed between the floating diffusion region FD and the gate 111.

The transfer transistor may be connected to another element through a contact portion, including a first contact CT1 connected to the gate 111, a second contact CT2 connected to the floating diffusion region FD, and a third contact connected to the ground region GND, and first interconnections connected to the contact portion. The first interconnections may include a via pattern formed through at least a portion of the interconnection pattern and the insulating layer.

A first upper insulating layer 120a may be provided on the first surface 10a on which the transfer gate 111 is formed. In some example embodiments, the first upper insulating layer 120a may be provided as a single layer or a multilayer structure. For example, the first upper insulating layer 120a may include a silicon oxide, a silicon nitride, a silicon oxynitride, or a low-κ dielectric material having a lower dielectric constant than the silicon oxide, but example embodiments are not limited thereto. For example, the first upper insulating layer 120a may include undoped silicate glass (USG).

A device isolation layer 150 may be provided between adjacent pixels PXL to partition each pixel PXL. For example, active regions AA of adjacent pixels PXL may be separated by the device isolation layer 150. For example, the device isolation layer 150 may be provided along a periphery of the photoelectric conversion region PD when viewed in plan view.

The device isolation layer 150 may include a first isolation layer 151, surrounding the photoelectric conversion region PD, and a second isolation layer 153 provided at a smaller depth than the first isolation layer 151 and provided adjacent only to a side of the floating diffusion region FD.

The device isolation layer 150 may include a first device isolation layer 150, formed in a deep trench 151t, and a second device isolation layer 150 interposed between the first device isolation layer 150 and the first substrate 10.

The first isolation layer 151 may be formed in the first substrate 10 to surround each of the pixels PXL. The first isolation layer 151 may be provided, for example, in such a manner that an insulating material is buried in a deep trench 151t formed by patterning the first substrate 10, for example, provided as deep trench isolation (DTI). The deep trench 151t may be provided to penetrate through the first substrate 10. For example, the deep trench 151t may be provided to penetrate through the first surface 10a and the second surface 10b of the first substrate 10.

In some example embodiments, the first isolation layer 151 may include a conductive isolation layer 151b, filled with a conductive material in the deep trench 151t, and an insulating layer 15a provided between the first substrate 10 and the conductive isolation layer 151b.

The conductive isolation layer 151b may include a crystalline semiconductor material such as polysilicon. In some example embodiments, the conductive isolation layer 151b may further include a dopant, and the dopant may include impurities of the first conductivity type or the second conductivity type. For example, the conductive isolation layer 151b may include doped polysilicon.

A negative voltage or a ground voltage may be applied to the conductive isolation layer 151b, resulting in reduced dark current.

The insulating liner 151a may be provided along a sidewall of the deep trench 151t. The insulating liner 151a may include, for example, a silicon nitride (S1₃N₄), a silicon oxide (SiO₂, silicate), and/or a silicon carbon nitride (SiCN)) and/or a high-κ metal oxide (for example, a hafnium oxide (HfOx), a zirconium oxide (ZrO₂), a titanium oxide (TiO₂), an aluminum oxide (Al₂O₃, alumina), or the like). The conductive isolation layer 151b may be spaced apart from the first substrate 10 by the insulating liner 151a. Accordingly, the conductive isolation layer 151b may be electrically separated from the first substrate 10 during the operation of the image sensor.

Unlike the first isolation layer 151 surrounding the active region AA, the second isolation layer 153 may be provided only in a portion. The second isolation layer 153 may be provided only on an edge of a pixel PXL, corresponding to a region in which the floating diffusion region FD is provided, when viewed in plan view. In some example embodiments, the second isolation layer 153 may be formed to surround at least a portion of the floating diffusion region FD such that the floating diffusion region FD is provided between the gate 111 and the second isolation layer 153 when viewed in plan view.

The second isolation layer 153 may be provided in a shallow trench 153t depressed by a depth (for example, a predetermined depth, desired depth, or generated depth) from the first surface 10a when viewed in cross-section. Unlike the deep trench 151t, the shallow trench 153t may be depressed only by a depth (for example, a predetermined depth, desired depth, or generated depth) from the first surface 10a of the first substrate 10 and may not penetrate through the first substrate 10.

In some example embodiments, the second isolation layer 153 may not be provided in portions other than a portion adjacent to the floating diffusion region FD. For example, the second isolation layer 153 may not be provided in the active region AA or a portion of a periphery of an edge of the pixel PXL spaced apart from the floating diffusion region FD.

The second isolation layer 153 may be provided on an edge immediately adjacent to the floating diffusion region FD to prevent or reduce a defect caused by a combination of electrons in the floating diffusion region FD and holes accumulated on a side of the first isolation layer 151, for example, dark current. When a negative voltage is applied to the first isolation layer 151, dark current may be reduced. However, when the second isolation layer 153 is not provided, holes accumulated adjacent to the first isolation layer 151 may strongly bind with electrons of the floating diffusion region FD. Such electron-hole pairs may be moved to the photoelectron conversion region to cause defects. To address such an issue, a second isolation layer 153 may be formed on an edge adjacent to the floating diffusion region FD to prevent or reduce the electrons of the floating diffusion region FD and the holes adjacent to the second isolation layer 153 from binding with each other. For example, the second isolation layer 153 may be formed only near the floating diffusion region FD, and thus the electrons of the floating diffusion region FD and the electrons near the second isolation layer 153 may be spaced apart from each other. As a result, drain leakage in the floating diffusion region FD induced by the transfer gate 111, for example, gate induced drain leakage (GIDL) may be reduced.

In the case of the related art, transistors, other than a transfer transistor, such as a reset transistor, a source follower transistor, a select transistor, and/or a dual conversion gain transistor may be provided in an active region depending on a configuration of a pixel. In this case, a second isolation layer was used as an isolation layer to isolate devices. However, in the case of the present disclosure, no transistor other than a transfer transistor is provided in the first substrate, so that a second isolation layer does not need to be provided in an active region. That is, due to an absence of additional transistors beyond a transfer transistor in the first substrate, a second isolation layer is not present.

As such, in some example embodiments, a portion of a periphery of an edge of a pixel spaced apart from the floating diffusion region with a gate interposed therebetween may be provided with only the first isolation layer without being provided with the second isolation layer.

For example, the second isolation layer 153 may be provided in a form in which an insulating material is buried in a shallow trench, for example, in the form of shallow trench isolation (STI). The second isolation layer 153 may be provided adjacent to the first surface 10a of the first substrate 10. For example, the second isolation layer 153 may extend from the first surface 10a of the first substrate 10. Although not illustrated, in some example embodiments, the second isolation layer 153 may be formed as a multilayer structure. The second isolation layer 153 may also include at least one of a silicon oxide, a silicon nitride, a silicon oxynitride, and combinations thereof, but example embodiments are not limited thereto.

A first isolation layer 151 may be provided on a lower side of a region in which the second isolation layer 153 is formed. For example, the first isolation layer 151 and the second isolation layer 153 may be provided to vertically stacked on the periphery of the active region AA adjacent to the floating diffusion region FD when viewed in cross-section. On the other hand, only the first isolation layer 151 may be provided to vertically extend on the periphery of the active region AA, in which the floating diffusion region FD is not provided, for example, in a region other than the first region.

A first lower insulating layer 120b may be provided on the second surface 10b. The first lower insulating layer 120b may cover the second surface 10b of the first substrate 10 and may be provided a multilayer structure. The first lower insulating layer 120b may include, for example, a silicon-based insulating material such as a silicon oxide, a silicon nitride, and/or a silicon oxynitride.

A color filter CF may be provided on the first lower insulating layer 120b.

The color filter CF may be disposed for each pixel PXL on the second surface 10b of the first substrate 10. For example, the color filters CF may be provided in locations corresponding to the photoelectric conversion regions PD. Each of the color filters CF may include one of a red filter, a blue filter, and a green filter. However, example embodiments are not limited thereto, and filters of other colors may be provided. The color filters CF may constitute color filter arrays. For example, the color filters CF may constitute an array arranged in a first direction D1 and a second direction D2 when viewed in plan view.

The micro lens ML may be disposed on the second surface 10b of the first substrate 10. For example, the micro lens ML may be disposed on the color filter CF. The micro lens ML may include a lens pattern and a planarized portion. The planarized portion of the micro lens ML may be provided on the color filters CF. A lens pattern may be provided on the planarized portion. The lens pattern may be formed to be integrated with the planarized portion, and the lens pattern and the planarized portion may be connected without a boundary. The lens pattern may include the same material as the planarized portion. As another example, the planarized portion may be omitted and the lens pattern may be directly disposed on the color filters CF.

The lens pattern may be hemispherical. The lens pattern may concentrate incident light. The lens pattern may be provided in a location corresponding to the photoelectric conversion regions PD of the first substrate 10. For example, the lens pattern may be provided on the photoelectric conversion region PD of the first pixel region of the first substrate 10.

The microlens ML may be transparent, allowing light to pass therethrough. The microlens ML may include an organic material such as a polymer. For example, the microlens ML may include a photoresist material or a thermosetting resin.

Although not illustrated, a protective layer may be provided on the microlens ML. The protective layer may include an organic material and/or an inorganic material. According to some example embodiments, the protective layer may include a silicon-containing material such as a silicon oxide, a silicon nitride, a silicon oxynitride, a silicon carbide, a silicon carbon oxide, a silicon carbon nitride, and/or a silicon carbon oxynitride. As another example, the protective layer may include an aluminum oxide, a zinc oxide, and/or a hafnium oxide. The second protective layer 170 may have insulating properties, but example embodiments are not limited thereto. The second protective layer 170 may allow light to pass therethrough.

In the image sensor having the above-described structure according to some example embodiments, full well capacitance (FWC) may be increased by extending a photoelectric conversion region. In addition, the image sensor according to some example embodiments may reduce dark current derived from shallow trench isolation. This will be described below in detail.

In the related arts, not only a transfer transistor but also other transistors (for example, a reset transistor, a source follower transistor, a select transistor, a dual conversion gain transistor, or the like) were formed together in a single substrate in which a photodiode is formed (for example, a first substrate). Transistors were formed together in pixels, for example, a transfer transistor was provided in a certain pixel and a transfer transistor and a source follower transistor were formed in a certain pixel. Accordingly, a separation layer was required between adjacent transistors to separate the adjacent transistors from each other. The separation layer, separating the adjacent transistors, corresponds to a shallow trench isolation layer. As such, more and larger separation layers provide more and large shallow trench isolation layers.

In the case of the related arts, transistors other than a transfer transistor were simultaneously formed in the first substrate and a shallow trench isolation layer was provided in the first substrate, so that a photoelectric conversion region was inevitably narrowed and, for example, photoelectric conversion expansion was substantially impossible due to other transistors and the shallow trench isolation layer.

In some example embodiments, an image sensor may be fabricated by forming a first structure and a second structure and then bonding the first and second structures. The first and second structure may be formed by forming only a transfer transistor, among a plurality of transistors such as the transfer transistor, a reset transistor, a source follower transistor, a select transistor, and a dual conversion gain transistor, on a first substrate and forming the remaining transistors, for example, the reset transistor, the source follower transistors, the select transistor, and the dual conversion gain transistor on another substrate (for example, a second substrate or a third substrate).

Thus, a shallow trench isolation layer separating the transfer transistor and other transistors in the first substrate may be removed. In addition, a shallow trench isolation layer provided between a first isolation layer and an active region, for example, between a P-well region and the first isolation layer may also be removed.

As a result, an area or a volume of a photoelectric conversion region may be expanded. The expansion of the photoelectric conversion region may result in an increase in full well capacitance (FWC). In addition, a shallow trench isolation layer provided in a portion surrounding an existing photoelectric conversion region, for example, a shallow trench isolation layer surrounding a photodiode to directly affect the photodiode may be removed to increase a portion in which a first isolation layer applied with a negative voltage is in contact with the photoelectric conversion region. As a result, a dark current reduction effect may be improved, for example, significantly improved and thereby improving the operation of the device.

Even in this case, by holding the shallow trench isolation layer in the floating diffusion region FD as it is, gate induced drain leakage (GIDL) in the floating diffusion region FD may be significantly reduced.

In some example embodiments, the structure of the transfer transistor in the first substrate is not limited thereto and may be provided in other forms. For example, a gate of the transfer transistor may have a planar transfer gate structure rather than the above-described vertical transfer gate structure.

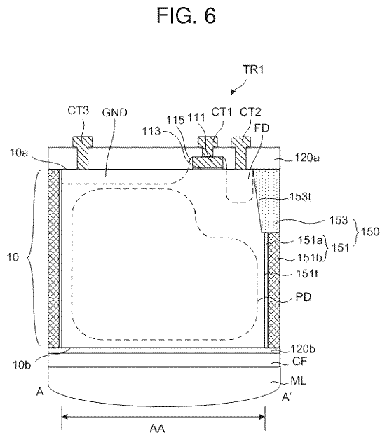

FIG. 6 illustrates an image sensor according to some example embodiments, and a cross-sectional view of an image sensor having a structure of a planar transfer gate 111.

Referring to FIG. 6, the transfer gate 111 may include a planar transfer gate 111 provided on a first surface 10a of a first substrate 10 with a gate insulating layer 113 interposed therebetween. In this case, the gate 111 is not provided with a substrate recess recessed into the first substrate 10, and thus may have a planar structure on the first surface 10a of the substrate.

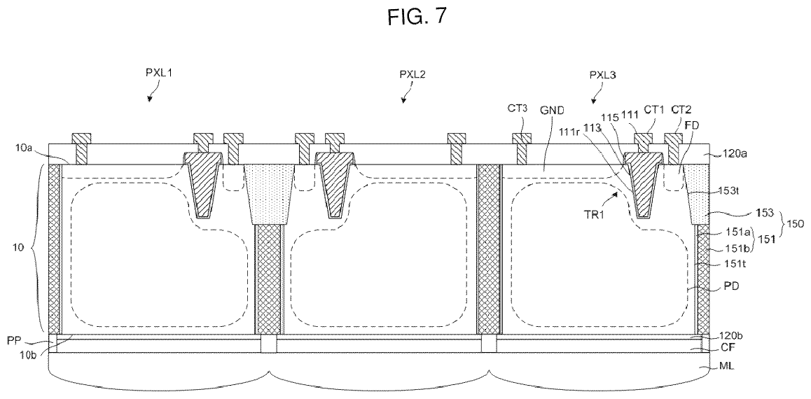

FIG. 7 is a cross-sectional view illustrating successively arranged pixels, in an image sensor according to some example embodiments.

Referring to FIG. 7, in an image sensor according to some example embodiments, the pixels PXL of some example embodiments may be arranged repeatedly in one direction, but adjacent pixels PXL may be formed to be symmetrical with respect to a first isolation layer 151. For example, when three adjacent pixels PXL are referred to as first to third pixels PXL1, PXL2, and PXL3, the first pixel PXL1 and the second pixel PXL2 may be symmetrically formed with the first isolation layer 151 between the first pixel PXL1 and the second pixel PXL2 interposed therebetween, and the second pixel PXL2 and the third pixel PXL3 may be symmetrically formed with the first isolation layer 151 between the first pixel PXL1 and the third pixel PXL3 interposed therebetween.

For example, when a floating diffusion region FD is provided on a side of an isolation layer 150 between two adjacent pixels, the first isolation layer 151 and the second isolation layer 153 may be provided between two adjacent pixels PXL. In addition, the first isolation layer 151 and the second isolation layer 153 may be shared with each other in adjacent portions. As described above, two adjacent pixels PXL may be symmetrically formed to simplify a process of forming the first and second isolation layers 151 and 153. In addition, although not illustrated, a third contact CT3 connected to the floating diffusion region FD may be shared by a plurality of adjacent pixels PXL, which will be described later in some example embodiments.

A fence pattern PP may be disposed on the device isolation layer 150. For example, the fence pattern PP may vertically overlap the second isolation layer 153. The fence pattern PP may have a planar shape corresponding to that of the second isolation layer 153. For example, the fence pattern PP may have a grid shape when viewed in plan view. The fence pattern PP may surround the color filters CF when viewed in plan view. The fence pattern PP may be interposed between two adjacent color filters CF. The plurality of color filters CF may be physically and optically separated from each other by the fence pattern PP. The fence pattern PP may include a material having a low refractive index. The material having the low refractive index may include a polymer and silica nanoparticles in the polymer. The low refractive index material may have insulating properties. As another example, the fence pattern PP may include metal and/or metal nitride. For example, the fence pattern PP may include titanium and/or titanium nitride.

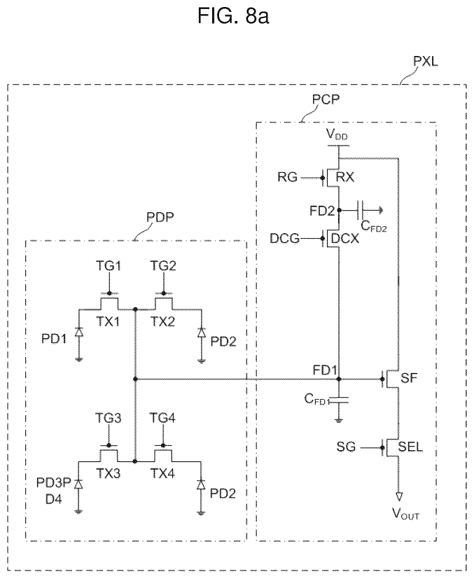

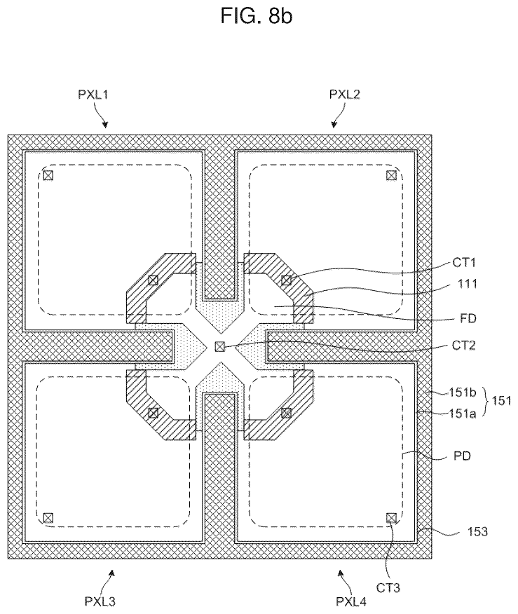

FIGS. 8A and 8B are a circuit diagram and a plan view illustrating that four adjacent pixels PXL share a floating diffusion region FD, in an image sensor according to some example embodiments.

Referring to FIGS. 8A and 8B, an image sensor may include first to fourth pixels PXL1, PXL2, PXL3, and PXL4. In some example embodiments, the first to fourth pixels PXL1, PXL2, PXL3, and PXL4 may be arranged in a first structure S1 in a single repetition unit.

The first to fourth pixels PXL1, PXL2, PXL3, and PXL4 may include first, second, third, and fourth photoelectric conversion elements PD1, PD2, PD3, and PD4, first, second, third, and fourth transfer transistors TX1, TX2, TX3, and TX4, and a first floating diffusion region FD1.

Similarly, in some example embodiments, a pixel PXL may include four pixel transistors RX, DCX, SF, and SEL. The above-mentioned pixel transistors may be shared by the first to fourth pixels PXL1, PXL2, PXL3, and PXL4. For example, the first to fourth transfer transistors TX1, TX2, TX3, and TX4 may share the first floating diffusion region FD1. Electrodes of transfer gates 111 of the first to fourth transfer transistors TX1, TX2, TX3, and TX4 may be controlled by first to fourth transfer signals TG1, TG2, TG3, and TG4, respectively.

Referring to FIG. 8B illustrating a specific embodiment in which the circuit of FIG. 8A is implemented, the first to fourth pixels PXL1, PXL2, PXL3, and PXL4 may be provided in a matrix of rows and columns. Among the first to fourth pixels PXL1, PXL2, PXL3, and PXL4, adjacent pixels may be symmetrically arranged. For example, adjacent pixels may be formed to be symmetrical with respect to a first isolation layer 151. For example, the first and second pixels PXL1 and PXL2 disposed adjacent to each other may be symmetrically formed with the first isolation layer 151 between the first pixel PX1 and the second pixel PXL2 interposed therebetween, the first and third pixels PXL1 and PXL3 may be symmetrically formed with the first isolation layer 151 between the first and third pixels PXL1 and PXL3 interposed therebetween, and the second and fourth pixels PXL2 and PXL4 may be symmetrically formed with the first isolation layer 151 between the second and fourth pixels PXL2 and PXL4 interposed therebetween.

In the first to fourth pixels PXL1, PXL2, PXL3, and PXL4, floating diffusion regions FD may be connected and shared with each other. To this end, a portion of an upper side of a second isolation layer 153 may be removed.

The above-described structure may allow image devices to be driven in various forms.

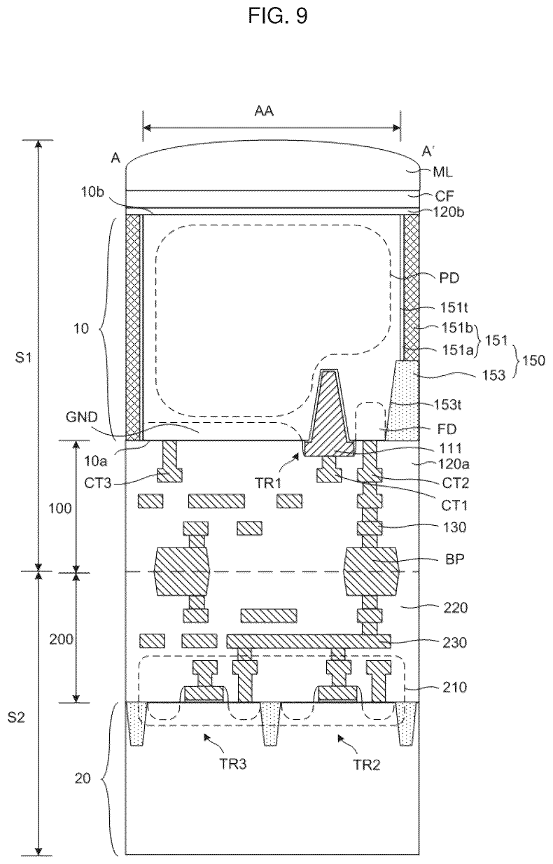

FIG. 9 is a cross-sectional view illustrating a first structure S1 and a second structure S2 are stacked, in an image sensor according to some example embodiments.

Referring to FIG. 9, an image sensor may include a first structure S1, in which a photodiode portion is formed in a pixel array region APS, and a second structure S2 in which a pixel circuit portion 210 is formed.

A plurality of pixels may correspond to the first structure S1 and the second structure S2. However, for ease of description, only one pixel disposed in a pixel array portion is illustrated in the drawing, and a pad portion is omitted from the drawing.

As described above, the first structure S1 may include a first substrate 10, and a first conductive pattern 100, a device isolation layer 150, a color filter CF, and a microlens ML provided on the first substrate 10. The first conductive pattern 100 may include a first transistor TR1 and a first interconnection portion 130, interconnections including a contacts connected to the first transistor TR1. The first structure S1 may be disposed in such a manner that a first surface 10a to be provided by inverting some example embodiments faces the second structure S2.

The second structure S2 may include a second substrate 20 and a second conductive pattern 200 provided on the second substrate 20.

The second conductive pattern 200 may include a pixel circuit portion 210 in which a plurality of transistors are formed, a second insulating layer 220 provided on the pixel circuit portion 210, and a second interconnection portion 230 connected to the pixel circuit portion 210.

The pixel circuit portion 210 may include at least one of remaining transistors other than the first transistor TR1 that a transfer transistor, among transistors constituting a pixel, for example, a reset transistor, a source flower transistor, a select transistor, or a dual conversion gain transistor. As an example, a source follower transistor as a second transistor TR2 and a dual conversion gain transistor as a third transistor TR3 are illustrated in the drawing.

A second insulating layer 220 may be provided on the pixel circuit portion 210. The second insulating layer 220 may be provided as a multilayer structure. Second interconnections 230, connected to the pixel circuit portion 210, may be provided on the second substrate 20 on which the second insulating layer 220 is formed. The second interconnections 230 may include an interconnection pattern and a via pattern formed through at least a portion of the second insulating layer 220.

A bonding portion, connecting the first structure S1 and the second structure S2, may be provided on an uppermost portion of the first interconnection patterns 130 (inverted to be disposed on a lowermost side in the drawing) and an uppermost portion of the second interconnection patterns 230. The bonding portion may include bonding pads BP disposed to oppose each other on the first structure S1 and the second structure S2. The bonding pad BP may be formed of various conductive materials that can be bonded by heating, or the like. The bonding pads BP may be integrated with each other through bonding after formation of the first structure S1 and the second structure S2. The bonding pad BP may include, for example, metal such as aluminum, copper, tungsten, titanium, tantalum, or alloys thereof. In some example embodiments, the bonding pad BP may be formed of copper, and thus the first and second structures S1 and S2 may be bonded through copper-copper bonding.

The first conductive pattern 100 of the first structure S1 and the second conductive pattern 200 of the second structure S2 may be connected to each other through the first interconnections 130, the bonding pads BP, and the second interconnections 230, which may allow a pixel to be driven.

An image sensor according to some example embodiments may be modified in various structures.

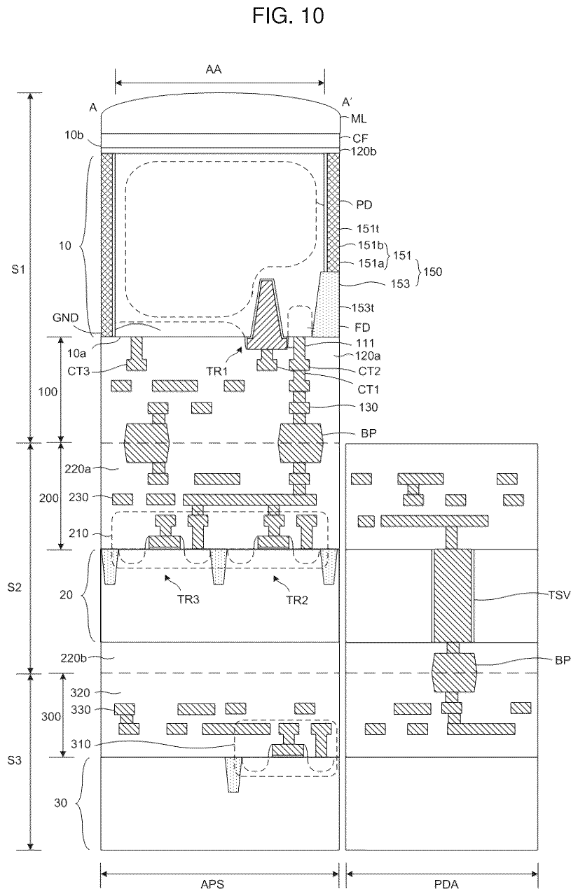

FIG. 10 is a cross-sectional view illustrating that a first structure to a third structure are sequentially stacked, in an image sensor according to some example embodiments.

A plurality of pixels PXL may correspond to a first structure S1 and a second structures S2. However, in the following drawing, a single pixel PXL disposed in a pixel array region APS and a portion of a pad region PDA are illustrated for ease of description. In addition, although the pixel array region APS and the pad region PDA are separately illustrated in FIG. 10, the pixel array region APS and the pad region PDA are not separated from each other and elements between the pixel array region APS and the pad region PDA are omitted. In the first structure S1, the pad region PDA may be provided or may not be provided. In this drawing, a pad region is not illustrated for ease of description.

Referring to FIG. 10, an image sensor may include a first structure S1 in which a photodiode portion in a pixel PXL is formed, a second structure S2 in which a pixel circuit portion 210 in the pixel PXL is formed, and a third structure S3 in which a logic circuit 310 driving a pixel is formed.

As described above, the first structure S1 may include a first substrate 10, and a first conductive pattern 100, a device isolation layer 150, a color filter CF, and a microlens ML provided on the first substrate 10. The first structure S1 may be disposed in such a manner that a first surface 10a to be provided by inverting some example embodiments faces the second structure S2.

The second structure S2 may include a second substrate 20 and a second conductive pattern 200 provided on the second substrate 20. The second conductive pattern 200 may include a pixel circuit portion 210 in which a plurality of transistors are formed, a second upper insulating layer 220A provided on the pixel circuit portion 210, and a second interconnection portion 230 connected to the pixel circuit portion 210.

The pixel circuit portion 210 may include at least one of remaining transistors other than a transfer transistor, among transistors constituting a pixel, for example, a reset transistor, a source flower transistor, a select transistor, or a dual conversion gain transistor.

A second upper insulating layer 220a may be provided on the pixel circuit portion 210. The second upper insulating layer 220a may be provided as a multilayer structure. Second interconnections 230, connected to the pixel circuit portion 210, may be provided on a second substrate 20 on which the second upper insulating layer 220a is formed. The second interconnections 230 may include an interconnection pattern and a via pattern formed through at least a portion of the second upper insulating layer 220a.

A bonding portion, connecting the first structure S1 and the second structure S2, may be provided on an uppermost portion of the first interconnection patterns 130 (inverted to be disposed on a lowermost side in the drawing) and an uppermost portion of the second interconnection patterns 230. The bonding portion may include bonding pads BP disposed to oppose each other on the first structure S1 and the second structure S2. The bonding pad BP may be formed of various conductive materials that can be bonded by heating, or the like. The bonding pads BP may be integrated with each other through bonding after formation of the first structure S1 and the second structure S2. The bonding pad BP may include, for example, metal such as aluminum, copper, tungsten, titanium, tantalum, or alloys thereof. In some example embodiments, the bonding pad BP may be formed of copper, and thus the first and second structures S1 and S2 may be bonded through copper-copper bonding.

The third structure S3 may be spaced apart from the first structure S1 with the second structure S2 interposed therebetween.

The third structure S3 may include a third substrate 30 and a third conductive pattern 300 provided on the third substrate 30.

The third conductive pattern 300 may include a logic circuit portion 310 in which a plurality of transistors are formed, a third insulating layer 320 provided on the logic circuit portion 310, and a third interconnection portion 330 connected to the logic circuit portion 310.

The logic circuit portion 310 may include various logic circuits and may include, for example, circuits processing pixel signals from pixels PXL. For example, the logic circuits may include a control register block, a timing generator, a row driver, a readout circuit, a ramp signal generator, or the like.

A third insulating layer 320 may be provided on the logic circuit portion 310. The third insulating layer 320 may be provided as a multilayer structure. Third interconnections 330, connected to the logic circuit portion 310, may be provided on the third substrate 30 on which the third insulating layer 320 is formed. The third interconnections 330 may include an interconnection pattern and a via pattern formed through at least a portion of the third insulating layer 320.

A bonding portion, connecting the second structure S2 and the third structure S3, may be provided on a lowermost portion of the second structure S2 and an uppermost portion of the third structure S3.

To this end, a second lower insulating layer and a bonding pad BP may be provided on the lowermost portion of the second structure S2, and a bonding pad BP may also be provided on the uppermost portion of the third structure S3. The bonding pad BP may be formed of various conductive materials that can be bonded by heating, or the like. The bonding pads BP may be integrated with each other through bonding after formation of the second structure S2 and the third structure S3. The bonding pad BP may include, for example, metal such as aluminum, copper, tungsten, titanium, tantalum, or alloys thereof. In some example embodiments, the bonding pad BP may be formed of copper, and thus the second and third structures S2 and S3 may be bonded through copper-copper bonding.

The second structure S2 and the third structure S3 may be electrically connected to each other through a through-via TSV formed in a pad region PDA of the second substrate 20 of the second structure S2. The through-via TSV may be formed by penetrating through upper and lower surfaces of the second substrate 20 and then filling an inside thereof with a conductive material. The second structure S2 and the third structure S3 may be electrically connected to each other through the through-via TSV.

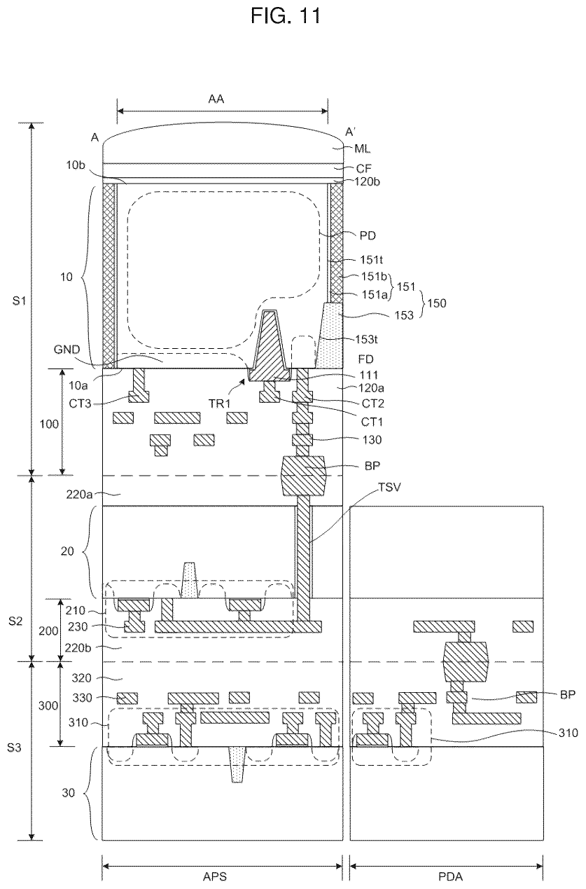

FIG. 11 is a cross-sectional view illustrating that a first structure to a third structure are sequentially stacked, in an image sensor according to some example embodiments.

Referring to FIG. 11, an image sensor may include a first structure S1 in which a photodiode portion in a pixel PXL is formed, a second structure S2 in which a pixel circuit portion 210 in the pixel PXL is formed, and a third structure S3 in which a driving logic circuit 310 is formed.

As described above, the first structure S1 may include a first substrate 10, and a first conductive pattern 100, a device isolation layer 150, a color filter CF, and a microlens ML provided on the first substrate 10. The first structure S1 may be disposed in such a manner that a first surface 10a to be provided by inverting some example embodiments faces the second structure S2.

The second structure S2 may include a second substrate 20 and a second conductive pattern 200 provided on the second substrate 20. The second conductive pattern 200 may include a pixel circuit portion 210 in which a plurality of transistors are formed, a second upper insulating layer 220a provided on the pixel circuit portion 210, and a second interconnection portion 230 connected to the pixel circuit portion 210.

Unlike the second structure S2 illustrated in FIG. 10, the second structure S2 of some example embodiments may be provided in an inverted form. For example, a first conductive pattern, such as the pixel circuit portion 210, may be provided on a lower surface rather than an upper surface of the second structure S2 of some example embodiments. The pixel circuit portion 210 may include at least one of remaining transistors other than a transfer transistor, among transistors constituting a pixel PXL, for example, a reset transistor, a source flower transistor, a select transistor, or a dual conversion gain transistor.

A second upper insulating layer 220a and a bonding pad BP may be provided on an upper surface of the second substrate 20 facing the first structure S1.

The pixel circuit portion 210 may be provided on a lower surface of the second substrate 20 facing the third structure S3, and a second lower insulating layer 220b may be provided on the pixel circuit portion 210. Second interconnections 230, connected to the pixel circuit portion 210, may be provided on the lower surface of the second substrate 20 on which the second lower insulating layer 220b is formed. The second interconnections 230 may include an interconnection pattern and a via pattern formed through at least a portion of the second lower insulating layer 220b.

A bonding portion, connecting the first structure S1 and the second structure S2, may be provided on an uppermost portion of the first interconnections 130 (inverted to be disposed on a lowermost side in the drawing) and an uppermost portion of the second structure S2. The bonding portion may include bonding pads BP disposed to oppose each other on the first structure S1 and the second structure S2. The bonding pad BP may be formed of various conductive materials that can be bonded by heating, or the like. The bonding pads BP may be integrated with each other through bonding after formation of the first structure S1 and the second structure S2. The bonding pad BP may include, for example, metal such as aluminum, copper, tungsten, titanium, tantalum, or alloys thereof. In some example embodiments, the bonding pad BP may be formed of copper, and thus the first and second structures S1 and S2 may be bonded through copper-copper bonding.

In this case, the first conductive pattern 100 of the first structure S1 and the second conductive pattern 200 of the second structure S2 may be connected to each other through a through-via TSV penetrating through the second substrate 20 in the pixel array region APS. The through-via TSV may be formed by penetrating through the upper and lower surfaces of the second substrate 20 and then filling an inside thereof with a conductive material. The first structure S1 and the second structure S2 may be electrically connected to each other through the through-via TSV.

The third structure S3 may be spaced apart from the first structure S1 with the second structure S2 interposed therebetween. The third structure S3 may include a third substrate 30 and a third conductive pattern 300 provided on the third substrate 30.

The third conductive pattern 300 may include a logic circuit portion 310 in which a plurality of transistors are formed, a third insulating layer 320 provided on the logic circuit portion 310, and a third interconnection portion 330 connected to the logic circuit portion 310.

The logic circuit portion 310 may include various logic circuits and may include, for example, circuits processing pixel signals from pixels PXL. For example, logic circuits may include a control register block, a timing generator, a row driver, a readout circuits, a ramp signal generator, or the like.

A third insulating layer 320 may be provided on the logic circuit portion 310. The third insulating layer 320 may be provided as a multilayer structure. Third interconnections 330, connected to the logic circuit portion 310, may be provided on the third substrate 30 on which the third insulating layer 320 is formed. The third interconnections 330 may include an interconnection pattern and a via pattern formed through at least a portion of the third insulating layer 320.

In the pad region PDA, a bonding portion may be provided on a lowermost portion of the second structure S2 and an uppermost portion of the third structure S3 to connect the second structure S2 and the third structure S3.

To this end, a second lower insulating layer and a bonding pad BP may be provided on the lowermost portion of the second structure S2, and a bonding pad BP may also be provided on the uppermost portion of the third structure S3. The bonding pad BP may be formed of various conductive materials that can be bonded by heating, or the like. The bonding pads BP may be integrated with each other through bonding after formation of the second structure S2 and the third structure S3. The bonding pad BP may include, for example, metal such as aluminum, copper, tungsten, titanium, tantalum, or alloys thereof. In some example embodiments, the bonding pad BP may be formed of copper, and thus the second and third structures S2 and S3 may be bonded through copper-copper bonding.

Although the second structure S2 and the third structure S3 are illustrated as being bonded to each other in the pad region PDA, example embodiments are not limited thereto. Even in the pixel array region APS, the second structure S2 and the third structure S3 may also be bonded to each other by the bonding pad BP.

As described above, according to some example embodiments, a reset transistor, a source follower transistor, a select transistor, a dual conversion gain transistor, or the like, formed on an existing first substrate, may be formed on another substrate separated from a first substrate, and a floating diffusion node may be bonded and connected to the substrate (a second substrate and/or a third substrate), different from the first substrate. Such a configuration may allow the substrate (the second substrate and/or the third substrate), different from the first substrate, to be formed (for example, easily or simply formed).

As set forth above, according to example embodiments, a photoelectric conversion region may have an expanded structure, so that full well capacitance may be increased. As a result, the quality of an image sensor may be improved.

In addition, a portion of elements affecting dark current may be removed in the photoelectric conversion region to obtain an effect of reducing the dark current.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While some example embodiments have been shown and described above, it will be apparent to those skilled in the art that modifications and variations could be made without departing from the scope of the present disclosure as defined by the appended claims.

Therefore, the technical scope of the present disclosure is not limited to the embodiments described herein, but may be determined by the claims.

What is claimed is:

1. An image sensor comprising:
a first structure and a second structure, each having at least one pixel and sequentially stacked in a vertical direction,
each of the pixels comprising
a photodiode portion in the first structure; and
a pixel circuit portion connected to the photodiode portion in the first structure,
the photodiode portion comprising
a photoelectric conversion region in a first substrate of the first structure;
a floating diffusion region spaced apart from the photoelectric conversion region;
a gate including a transfer channel between the photoelectric conversion region and the floating diffusion region; and
a device isolation layer surrounding the photoelectric conversion region, and
the device isolation layer comprising a first isolation layer, surrounding the photoelectric conversion region, and a second isolation layer, having a smaller depth than the first isolation layer and adjacent to only a side of the floating diffusion region, when viewed in plan view.

2. The image sensor of claim 1, wherein
the first substrate has a first surface and a second surface opposing the first surface, the first isolation layer is a deep trench isolation layer penetrating through the first surface and the second surface, and the second isolation layer is a shallow trench isolation layer depressed by a depth from the first surface.

3. The image sensor of claim 2, wherein
a ground voltage or a negative voltage is applied to the first isolation layer.

4. The image sensor of claim 2, wherein
the first isolation layer and the second isolation layer are stacked in the vertical direction in a region adjacent to the floating diffusion region, and only the first isolation layer is in a region other than the region adjacent to the floating diffusion region.

5. The image sensor of claim 1, wherein
each of the pixels comprises a plurality of transistors, and
the photodiode portion comprises a portion of the plurality of transistors, and the pixel circuit portion comprises a remaining portion of the plurality of transistors.

6. The image sensor of claim 5, wherein
the photodiode portion comprises a transfer transistor, and the gate is a transfer gate.

7. The image sensor of claim 6, wherein
the transfer gate is a vertical transfer gate formed in a recess extending inwardly of the first substrate from the first surface of the first substrate.

8. The image sensor of claim 6, wherein
the gate is a planar transfer gate on the first surface of the substrate with a gate insulating layer interposed therebetween.

9. The image sensor of claim 6, wherein
the pixel circuit portion comprises at least one of a reset transistor, a source follower transistor, a select transistor, or a dual conversion gain transistor.

10. The image sensor of claim 1, further comprising:
a bonding portion connecting the first structure and the second structure to each other.

11. The image sensor of claim 10, wherein
the bonding portion comprises copper-copper bonding.

12. The image sensor of claim 1, wherein
each of the pixels comprises a first pixel and a second pixel adjacent to each other, and
the floating diffusion region is shared by the first pixel and the second pixel.

13. The image sensor of claim 12, wherein
the first pixel and the second pixel are symmetrically provided with the first isolation layer, between the first pixel and the second pixel, interposed therebetween.

14. The image sensor of claim 5, further comprising:
a third structure stacked to oppose the first structure with the second structure interposed therebetween.

15. The image sensor of claim 14, wherein
the third structure comprises a logic circuit connected to the first structure and the second structure to drive transistors of each of the pixels.

16. The image sensor of claim 15, wherein
at least a portion of the remaining transistors, other than a transfer transistor, is provided in the third structure.

17. The image sensor of claim 14, wherein
the second structure comprises a second substate, a conductive pattern provided on the second substrate, and a through-via penetrating through the second substrate, and the first structure and the third structure are connected to each other through the through-via.

18. The image sensor of claim 1, further comprising:
a ground region provided between the gate and the device isolation layer,
wherein the ground region includes impurities of a first conductivity type, and the photoelectric conversion region and the floating diffusion region include impurities of a second conductivity type opposite to the first conductivity type.

19. An image sensor comprising:
a photoelectric conversion region in a first substrate having a first surface and a second surface;
a floating diffusion region in the first substrate to be spaced apart from the photoelectric conversion region;
a gate of a transfer transistor on a side of the first surface of the first substrate as a transfer channel between the photoelectric conversion region and the floating diffusion region; and
a device isolation layer surrounding the photoelectric conversion region, the device isolation layer comprising a first isolation layer, surrounding the photoelectric conversion region, and a second isolation layer, having a smaller depth than the first isolation layer and adjacent to only a side of the floating diffusion region, when viewed in plan view.

20. An image sensor comprising:
a pixel comprising a plurality of transistors,
a first structure, a second structure, and a third structure sequentially stacked in vertical direction, the first structure comprising a transfer transistor among the plurality of transistors, the second structure comprising remaining transistors other than the transfer transistor, and the third structure a logic circuit, the first structure comprising
a device isolation layer surrounding an active region in a first substrate having the first surface and the second surface;
a photoelectric conversion region in the active region;
a floating diffusion region in the active region and spaced apart from the photoelectric conversion region; and
a gate of the transfer transistor in the active region on a side of the first surface of the first substrate as a transfer channel between the photoelectric conversion region and the floating diffusion region, and
the device isolation layer comprising a first isolation layer, surrounding the photoelectric conversion region, and a second isolation layer, having a smaller depth than the first isolation layer, when viewed in plan view, the first isolation layer and the second isolation layer stacked in a vertical direction in a first region adjacent to the floating diffusion region, and the second isolation layer is in the vertical direction in a region other than the first region.
